(19) United States
(12) Patent Application Publication
(10) Pub. No.: US 2026/0243956 A1
(43) Pub. Date: Aug. 20, 2026

(54) OPTICAL SEMICONDUCTOR ELEMENT

(71) Applicant: MITSUBISHI ELECTRIC CORPORATION, Tokyo (JP)

(72) Inventors: Satoshi NISHIKAWA, Tokyo (JP); Masahiro MATSUURA, Tokyo (JP); Ryoko SUZUKI, Tokyo (JP)

(73) Assignee: MITSUBISHI ELECTRIC CORPORATION, Tokyo (JP)

(21) Appl. No.: 19/159,334

(22) PCT Filed: May 15, 2023
(86) PCT No.: PCT/JP2023/018127

§ 371 Date: Aug. 25, 2025

(51) Int. Cl. G02B 6/122; H01S 5/026

(52) U.S. Cl. CPC G02B 6/1228; H01S 5/0265

(57) ABSTRACT

An optical semiconductor element according to the present disclosure includes: a first waveguide; a tapered waveguide in which a waveguide width decreases toward the tapered waveguide; a second waveguide having a waveguide width smaller than that of the first waveguide; and a gain tapered waveguide in which a waveguide width increases along a beam propagation direction, wherein a high-order mode beam is excited in the tapered waveguide as a fundamental mode beam entering from the first waveguide propagates, and the gain tapered waveguide, the first waveguide, and the transparent tapered waveguide are arranged along the beam propagation direction, and there is a focus position where an intensity of the propagating beam is focused at one location through interference between the fundamental mode beam and the high-order mode beam in the tapered waveguide, and the tapered waveguide and the second waveguide are connected at the focus position.

### TECHNICAL FIELD

The present disclosure relates to an optical semiconductor element.

### BACKGROUND ART

As one of devices for performing optical communication, an optical semiconductor element that generates and outputs a laser beam using a semiconductor is known. For example, an optical semiconductor element in which a laser section, an electro absorption (EA) optical modulator, and a semiconductor optical amplifier (SOA) are integrated is known (for example, Patent Document 1).

In such a conventional optical semiconductor element, the laser section generates a laser beam in accordance with injected current. The EA modulator has a function of performing modulation using an effect that the optical absorption spectrum of a semiconductor layer changes in accordance with applied voltage, and generates a modulated laser beam by modulating the laser beam generated by the laser section. The semiconductor optical amplifier has a function of increasing the beam intensity by occurrence of stimulated emission in accordance with injected current, and generates an amplified laser beam by amplifying the modulated laser beam modulated by the EA modulator.

However, as optical communication technology spreads, further increase in beam output of an optical semiconductor element is being expected. As a SOA suitable for output increase, the following element structure has been reported: a SOA having such a taper shape that the waveguide width increases along the propagation direction of a beam so as to expand the spot size is integrated and a spot-size converter having a long size is integrated for favorably coupling an output beam with an optical fiber (for example, Patent Document 2).

### CITATION LIST

### Patent Document

Patent Document 1: Japanese Laid-Open Patent Publication No. 2019-160840
Patent Document 2: Japanese Laid-Open Patent Publication No. 8-195525

### SUMMARY OF THE INVENTION

### Problem to be Solved by the Invention

By providing the SOA at a stage subsequent to the optical semiconductor element, it becomes possible to increase the beam output. In a drive condition in which a beam is amplified and a photon density at an active layer position in the SOA increases, carriers with current injected are consumed through stimulated emission so as to be depleted, and due to this and the like, gain saturation occurs. Therefore, in the semiconductor optical integrated element described in Patent Document 1, in a case of using a SOA having a uniform waveguide width, amplification of the beam intensity is saturated, so that beam output increase higher than the saturation intensity is restricted.

In the element structure of the semiconductor laser described in Patent Document 2 in which the SOA having such a taper shape that the waveguide width increases along the propagation direction of a beam so as to expand the spot size in order to achieve beam output increase, the beam intensity is amplified, and meanwhile, increase in the photon density is suppressed by expansion of the spot size in the horizontal direction, so that gain saturation is mitigated, whereby beam output increase is achieved.

In the guided mode shape of an output beam from the SOA having a taper shape for expanding the spot size, a circularity which is the ratio of the vertical-direction size and the horizontal-direction size in the guided mode is low, so that coupling with an optical fiber is deteriorated. Patent Document 2 discloses the element structure in which the spot-size converter having a taper shape for reducing the spot size is integrated at the stage subsequent to the SOA, thereby making the guided mode shape closer to a circle, thus improving coupling with an optical fiber. However, for converting the spot shape so that the guided mode shape expanded in the horizontal direction becomes closer to a circle, a long-size conversion element is needed, resulting size increase in the optical semiconductor element.

The present disclosure has been made to solve the above problem, and an object of the present disclosure is to provide an optical semiconductor element in which a guided beam having such a guided mode shape that the spot size in the horizontal direction of a semiconductor substrate is large and the circularity is low can be converted to such a guided mode shape that the circularity is high and coupling with an optical fiber is easy.

### Means to Solve the Problem

An optical semiconductor element according to the present disclosure includes: a first wavequide which is formed above a semiconductor substrate and in which a propagating beam in a high-order mode is allowed; a tapered waveguide which is formed above the semiconductor substrate and of which one end is connected to another end of the first waveguide and a wavequide width decreases toward another end of the tapered waveguide; and a second waveguide which is formed above the semiconductor substrate and of which one end is connected to the tapered waveguide, the second waveguide having a smaller waveguide width than a waveguide width of the first waveguide. The tapered waveguide has such a taper shape that a high-order mode beam is excited in the tapered waveguide as a fundamental mode beam entering from the other end of the first wavequide propagates, there is a focus position where an intensity of the propagating beam is focused at one location through interference between the fundamental mode beam and the high-order mode beam in the tapered wavequide, and the tapered wavequide and the second waveguide are connected at the focus position.

### Effect of the Invention

The optical semiconductor element according to the present disclosure provides an effect of obtaining an optical semiconductor element in which a guided beam having such a guided mode shape that the spot size in the horizontal direction of a semiconductor substrate is large and the circularity is low can be converted to such a guided mode shape that the circularity is high and coupling with an optical fiber is easy.

### BRIEF DESCRIPTION OF THE DRAWINGS

FIG. 1 FIG. 1A and FIG. 1B are top views showing optical semiconductor elements according to embodiment 1;

FIG. 2 is a sectional view showing the optical semiconductor element according to embodiment 1;

FIG. 3 shows a beam intensity distribution of a propagating beam in the optical semiconductor element according to embodiment 1;

FIG. 4 shows a beam intensity distribution of a propagating beam in an optical semiconductor element according to a modification of embodiment 1;

FIG. 5 FIG. 5A is a top view showing the optical semiconductor element according to embodiment 1, and FIG. 5B and FIG. 5C are top views showing optical semiconductor elements according to other modifications of embodiment 1;

FIG. 6 is a top view showing an optical semiconductor element according to embodiment 2;

FIG. 7 is a sectional view showing the optical semiconductor element according to embodiment 2;

FIG. 8 FIG. 8A and FIG. 8B are top views showing optical semiconductor elements according to modification 1 of embodiment 2;

FIG. 9 FIG. 9A and FIG. 9B are top views showing optical semiconductor elements according to modification 2 of embodiment 2;

FIG. 10 FIG. 10A is a top view showing the optical semiconductor element according to embodiment 2, and

FIG. 10B, FIG. 10C, and FIG. 10D are top views showing optical semiconductor elements according to modification 3 of embodiment 2;

FIG. 11 is a top view showing an optical semiconductor element according to modification 4 of embodiment 2;

FIG. 12 is a top view showing an optical semiconductor element according to embodiment 3;

FIG. 13 is a sectional view showing the optical semiconductor element according to embodiment 3.

### DESCRIPTION OF EMBODIMENTS

Optical semiconductor elements according to embodiments will be described with reference to the drawings. The same or corresponding components may be denoted by the same reference characters and repetition of the description thereof may be omitted.

### Embodiment 1

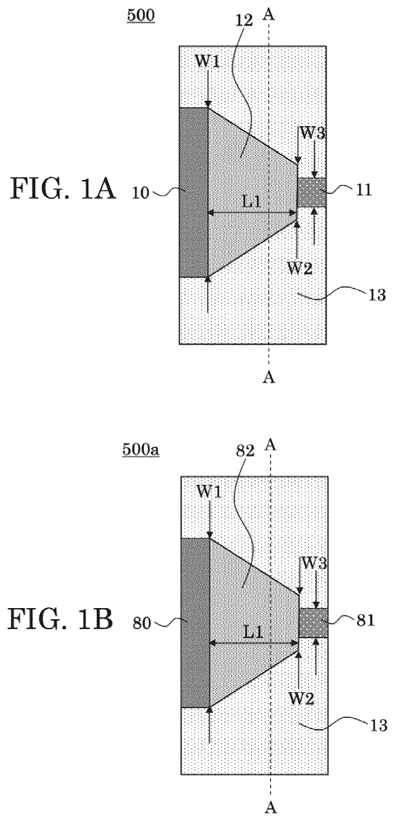

FIG. 1A and FIG. 1B are top views showing optical semiconductor elements 500 and 500a according to embodiment 1. For facilitating understanding of the drawings, scales in a beam propagation direction of a waveguide and a direction perpendicular to the beam propagation direction are shown in a state of being reduced in the beam propagation direction.

An optical semiconductor element 500 according to embodiment 1 includes a first waveguide 10, a transparent tapered waveguide 12, a second waveguide 11, and a lateral cladding region 13.

As shown in FIG. 1A, the first waveguide 10 having a waveguide width W1, the tapered waveguide (hereinafter, referred to as transparent tapered waveguide 12) of which waveguide width at one end on the first wavequide 10 side is W1, a waveguide width at another end is W2, and a waveguide length in the beam propagation direction is L1, and which is transparent for a wavelength (hereinafter, referred to as used wavelength) of the propagating beam, i.e., does not absorb the propagating beam, and the second waveguide 11 having a waveguide width W3, are connected in this order from the left side of FIG. 1A, i.e., along the beam propagation direction. The second waveguide 11 is also transparent for the used wavelength, as with the transparent tapered wavequide 12. That is, the second waveguide 11 and the transparent tapered waveguide 12 can be considered to be transparent waveguides for the used wavelength. The reason for using the transparent waveguides is that, since a part at the focused position where the beam intensity increases in the waveguide, i.e., a subsequent part of the transparent tapered wavequide 12 and the second waveguide 11, are transparent, occurrence of deterioration in a signal beam caused by gain saturation due to an excessive photon density, etc., can be suppressed. Thus, a mode conversion element, i.e., the transparent tapered waveguide 12, which converts a laser beam in the first wavequide 10 which has a low circularity and is difficult to be coupled with an optical fiber, to a laser beam in the second waveguide 11 which has a high circularity and is improved in the coupling rate with an optical fiber, can be downsized while deterioration in a signal beam can be suppressed.

The taper shape of the transparent tapered waveguide 12 has a relationship of the waveguide width W1>the waveguide width W2. That is, the transparent tapered waveguide 12 has such a shape that the waveguide width decreases along the beam propagation direction from the waveguide width W1 on the one end side of the transparent tapered waveguide 12 to the waveguide width W2 on the other end side. It is preferable that L1/W1 which is the ratio of the waveguide length L1 of the transparent tapered wavequide 12 and the waveguide width W1 on the one end side of the transparent tapered wavequide 12, i.e., the first waveguide 10 side, is not greater than 10. With this configuration, the mode conversion element, i.e., the transparent tapered waveguide 12, which converts a laser beam in the first wavequide 10 which has a low circularity and is difficult to be coupled with an optical fiber, to a laser beam in the second waveguide 11 which has a high circularity and is improved in the coupling rate with an optical fiber, can be downsized.

In the optical semiconductor element 500, the lateral cladding region 13 is provided in the region other than regions where the first waveguide 10, the transparent tapered waveguide 12, and the second waveguide 11 are formed.

Examples of size combinations of the waveguide widths W1, W2, and W3 of the first waveguide 10, the transparent tapered waveguide 12, and the second waveguide 11 are as follows: with respect to a used wavelength of 1.3 μm, W1=10.0 μm, W2=3.5 μm, W3=2.0 μm, and L1=80 μm, or W1=7.0 μm, W2=2.8 μm, W3=2.0 μm, and L1=50 μm. The taper shape of the transparent tapered waveguide 12 exhibits a trapezoidal shape in a plan view.

FIG. 1B is a top view of an optical semiconductor element 500a obtained by replacing the waveguides composing the optical semiconductor element 500 shown in FIG. 1A with gain waveguides. That is, the optical semiconductor element 500a includes a gain first waveguide 80, a gain second wavequide 81, a gain tapered waveguide 82, and the lateral cladding region 13. Hereinafter, the transparent tapered waveguide 12 and the gain tapered waveguide 82 may be collectively referred to simply as a tapered waveguide. In the following description, the case shown in FIG. 1A is described, while the optical semiconductor element 500a shown in FIG. 1B provides, in addition to effects provided by the optical semiconductor element 500 shown in FIG. 1A described later, an effect of enabling output increase of the optical semiconductor element as a result of amplification of the intensity of a propagating beam. The reason is as follows. In the case of using the gain tapered waveguide 82, the beam intensity in the gain tapered waveguide 82 and the output beam intensity in the gain second waveguide 81 can be increased under such a beam intensity condition that signal deterioration is slight in a nonlinear phenomenon such as gain saturation which is likely to occur under a high beam intensity and can cause beam signal deterioration.

### Cross-Section Structure of Optical Semiconductor Element According to Embodiment 1

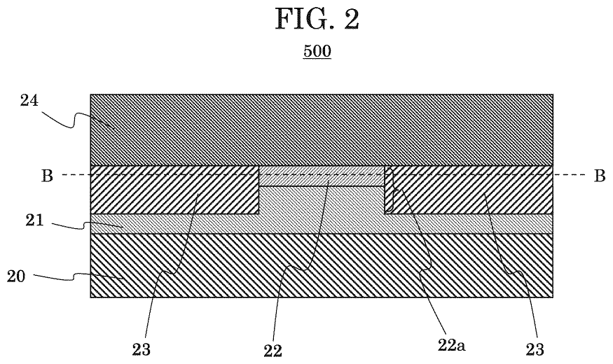

FIG. 2 is a sectional view showing the optical semiconductor element 500 according to embodiment 1, and shows a cross-section along line A-A in FIG. 1A. The optical semiconductor element 500 includes a transparent waveguide mesa portion 22a having a protrusion shape in a cross-section and composed of a lower cladding layer 21 and a transparent waveguide core layer 22 formed above a semiconductor substrate 20, a lateral cladding layer 23 formed at both side surfaces of the transparent waveguide mesa portion 22a, and an upper cladding layer 24 formed on an upper surface of the transparent waveguide mesa portion 22a and an upper surface of the lateral cladding layer 23.

### Method for Manufacturing Optical Semiconductor Element According to Embodiment 1

On the semiconductor substrate 20, the lower cladding layer 21 and the transparent wavequide core layer 22 are sequentially laminated by epitaxial crystal growth or the like. An etching mask having a desired shape is formed using photolithography technology and etching technology. Then, using dry etching or the like, a lateral cladding layer 23 part is etched and removed until reaching a certain position in the lower cladding layer 21 through the entire transparent waveguide core layer 22, thus forming the transparent waveguide mesa portion 22a having a protrusion shape. Subsequently, the lateral cladding layer 23 is formed by burying crystal growth so as to bury both side surfaces of the transparent waveguide mesa portion 22a. After the burying crystal growth, the upper cladding layer 24 is laminated by epitaxial crystal growth or the like, whereby the cross-section structure shown in FIG. 2 is obtained.

The material forming the transparent waveguide core layer 22 is selected so that the refractive index of the transparent waveguide core layer 22 becomes higher than the refractive indices of the lower cladding layer 21, the lateral cladding layer 23, and the upper cladding layer 24.

Examples of such materials are as follows: the semiconductor substrate 20, the lower cladding layer 21, the lateral cladding layer 23, and the upper cladding layer 24 are made of InP, and the transparent waveguide core layer 22 is made of InGaAsP or InAlGaAs which is a composition transparent for a beam having the used wavelength. These layers can be formed by epitaxial crystal growth on the semiconductor substrate, using a known crystal growth technique.

Also in a cross-section other than the cross-section along line A-A in FIG. 1A, a similar cross-section structure is exhibited except that the waveguide width of the transparent waveguide core layer 22 is different. The thickness of the upper cladding layer 24 is preferably 2.0 μm, for example, and the thickness of the transparent waveguide core layer 22 is preferably 0.4 μm, for example.

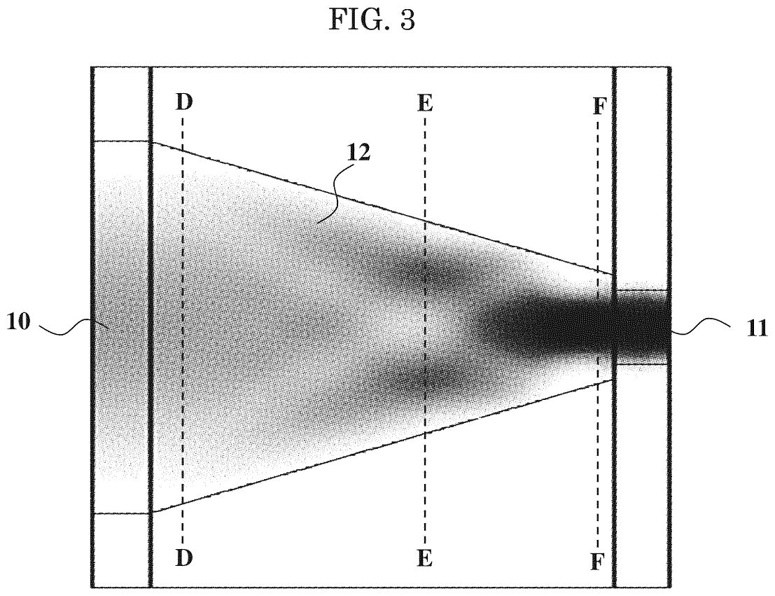

Regarding the optical semiconductor element 500 according to embodiment 1 shown in the top view in FIG. 1A, a beam intensity distribution of a propagating beam when a fundamental mode beam enters from the first waveguide 10 side is calculated using a commercial wavequide simulator, and a result thereof is shown in FIG. 3. The beam intensity is displayed in grayscale and a darker part represents a greater beam intensity. A fundamental mode beam that has entered from one end of the first waveguide 10 goes into the transparent tapered waveguide 12 from the other end of the first waveguide 10 and propagates while the waveguide width is narrowed.

A propagating beam at a D-D line position in FIG. 3 is very similar to a propagating beam in the first waveguide 10. As the propagating beam propagates in the transparent tapered waveguide 12, the fundamental mode beam is converted to a high-order mode beam, and through interference between the fundamental mode beam and the high-order mode beam, the shape of the beam intensity in the entire propagating beam is complicated. In the propagating beam at an E-E line position in FIG. 3, a beam intensity at a center part of the optical semiconductor element 500 is not maximum because of interference between guided mode beams for different orders, thus exhibiting a beam intensity shape splitting in a bimodal shape.

At an F-F line position in FIG. 3, the phases of the guided mode beams for different orders match each other and are focused to be a beam having a smaller beam size than the propagating beam in the first waveguide 10 and having a unimodal beam intensity shape. At the focus position, connection is made to the second waveguide 11 that matches the size of the focused beam, whereby the propagating beam in the first waveguide 10 can be coupled with the second waveguide 11 at low loss. That is, the transparent tapered waveguide 12 composing the optical semiconductor element 500 according to embodiment 1 can be considered to operate as a one-output one-input MMI (multimode interferometer) capable of mode size conversion.

In a case where the transparent tapered waveguide 12 has a significantly long shape, the fundamental mode beam propagates adiabatically in an optical sense. Therefore, conversion to a high-order mode beam does not occur and the intensity distribution of the propagating beam remains unimodal, so that the intensity distribution of the propagating beam as shown in FIG. 3 is not exhibited.

According to a calculation result in the case shown in FIG. 3, loss in the beam intensity of the guided beam transferred from the first waveguide 10 to the second waveguide 11 is 0.06 dB, which is a low loss value. With the element structure of the optical semiconductor element 500 according to embodiment 1, it becomes possible to provide an optical semiconductor element in which a guided beam having such a guided mode shape that the spot size in the horizontal direction of the semiconductor substrate 20 is large and the circularity is low can be converted to such a guided mode shape that the circularity is high and coupling with an optical fiber is easy.

That is, in the optical semiconductor element 500 according to embodiment 1, the transparent tapered wavequide 12 has such a taper shape that a high-order mode beam is excited in the transparent tapered waveguide 12 as the fundamental mode beam entering from the other end of the first wavequide 10 propagates, there is a focus position where the intensity of the propagating beam is focused at one location through interference between the fundamental mode beam and the high-order mode beam in the transparent tapered waveguide 12, and the transparent tapered waveguide 12 and the second waveguide 11 are connected at the focus position, thus providing an effect of making it possible to provide an optical semiconductor element in which a guided beam having such a guided mode shape that the spot size in the horizontal direction is large and the circularity is low is converted to such a guided mode shape that the circularity is high and coupling with an optical fiber is easy. It is desirable that the above focus position is a position where a beam entering from the first waveguide 10 is first focused while propagating. That the transparent tapered wavequide 12 and the second waveguide 11 are connected at the focus position means that both waveguides are connected within a range of ±5 times the beam wavelength, which is a range where the focusing property is kept excellent, centered at the focus position.

The feature of the element structure of the optical semiconductor element 500 according to embodiment 1 in which there is a focus position where the intensity of the propagating beam is focused at one location through interference between the fundamental mode beam and the high-order mode beam in the transparent tapered waveguide 12, and the transparent tapered wavequide 12 and the second wavequide 11 are connected at the focus position, can be realized by repeating calculation using the above waveguide simulator while changing parameters which are the wavequide width W1 of the first waveguide 10, the wavequide width W2 on the second waveguide 11 side of the transparent tapered waveguide 12, the waveguide length L1 of the transparent tapered waveguide 12, the wavequide width W3 of the second waveguide 11, and the like, for example.

### Modification of Embodiment 1

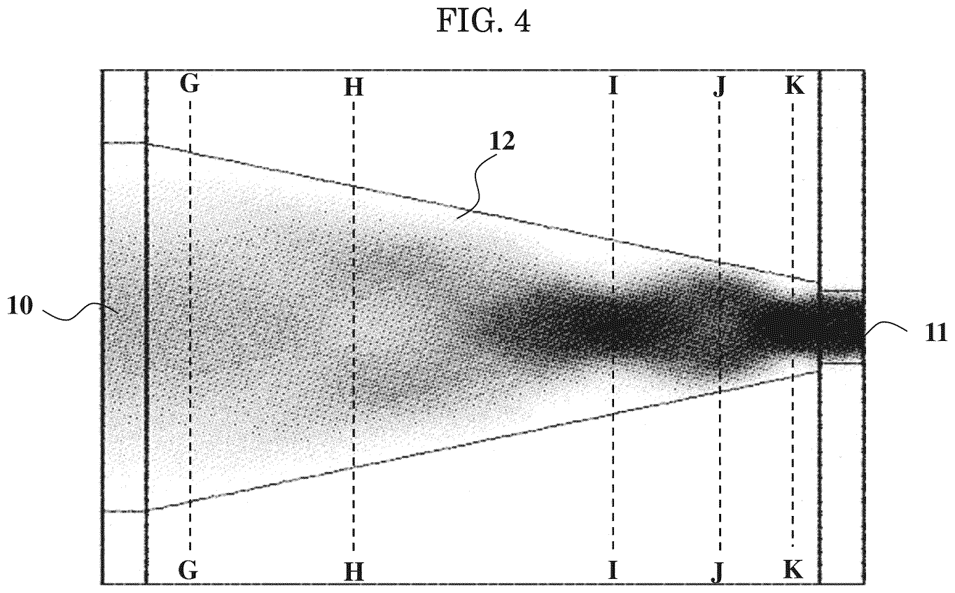

FIG. 4 shows a result obtained by calculating a beam intensity distribution of a propagating beam when a fundamental mode beam enters from the first waveguide 10 side in an optical semiconductor element according to a modification of embodiment 1, using a commercial waveguide simulator. Combination of sizes in the optical semiconductor element in FIG. 4 are as follows: with respect to a used wavelength of 1.3 μm, W1=10.0 μm, W2=2.8 μm, W3=2.0 μm, and L1=150 μm. The condition of beam entry is the same as in FIG. 3.

A beam intensity shape of a propagating beam at a G-G line position in FIG. 4 is similar to the fundamental mode of the first waveguide 10, as with the beam intensity shape of the propagating beam at the D-D line position in FIG. 3. Beam intensity shapes at an H-H line position and an I-I line position are qualitatively the same as beam intensity shapes at the E-E line position and the F-F line position in FIG. 3, i.e., a bimodal shape and a shape of focusing at one location at the waveguide center, respectively. Further, as the beam propagates, the beam intensity shape becomes a bimodal shape again at a J-J line position, and then becomes a focused shape for the second time at a K-K line position. FIG. 4 shows such an element structure that the focused beam is coupled with the second waveguide 11 having a matched waveguide width.

Between the size of the focused beam at the I-I line position and the size of the focused beam at the K-K line position, the one at the K-K line position is smaller and thus the reduction rate of the beam size is lower at the I-I line position. At focus positions for the second and subsequent times, as the focus position becomes closer to the distal end of the taper shape, the intervals between the focus positions arising repeatedly become closer to each other. Therefore, in coupling with the second waveguide 11 having a uniform waveguide width, there is a problem that the coupling rate sensitively changes with variation in the element structure. That is, in comparison of the element structures shown in FIG. 3 and FIG. 4, the structure in which the focus position appears earlier as in FIG. 3 exhibits a greater tolerance with respect to variation in the element structure for beam coupling, and therefore is preferable as an optical semiconductor element.

### Other Modifications of Embodiment 1

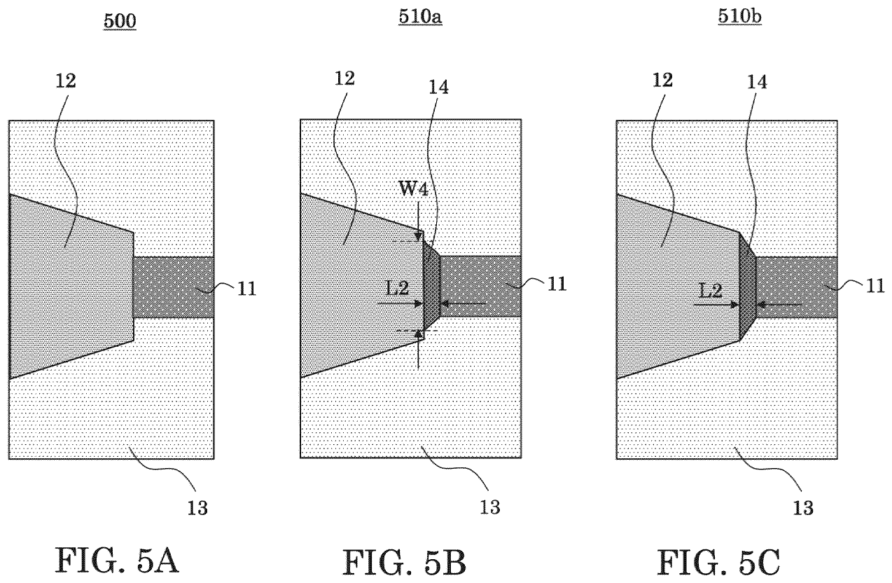

FIG. 5B and FIG. 5C are top views of optical semiconductor elements 510a and 510b according to other modifications of embodiment 1. FIG. 5A is an enlarged view of a part around the connection part between the transparent tapered wavequide 12 and the second waveguide 11 in the top view of the optical semiconductor element 500 according to embodiment 1 shown in FIG. 1A. The element structures of the optical semiconductor element 510a shown in FIG. 5B and the optical semiconductor element 510b shown in FIG. 5C are modifications in which the element structure of the optical semiconductor element 500 shown in FIG. 5A is modified.

In the element structures shown in FIG. 5B and FIG. 5C in the optical semiconductor elements according to the other modifications of embodiment 1, a connection transparent tapered waveguide 14 for connecting the transparent tapered waveguide 12 and the second waveguide 11 is provided therebetween. The connection transparent tapered waveguide 14 has a waveguide width W4 at the connection part with the transparent tapered waveguide 12, and is set to a wavequide width not greater than the waveguide width W2 of the transparent tapered waveguide 12. At the connection part with the second waveguide 11, the waveguide width of the connection transparent tapered waveguide 14 is set to the Same waveguide width as the waveguide width W3 of the second waveguide 11. The waveguide length in the beam propagation direction of the connection transparent tapered wavequide 14 is L2.

The structure in which the tapered waveguide is provided at the connection part between the MMI and the input/output waveguide has effects of mitigating the phenomenon in which loss in connection sensitively changes with variation in the element structure and reducing the reflectance of a returning beam reflected at the connection interface, and therefore this structure is desirable.

For the waveguide length L2 in the beam propagation direction of the connection transparent tapered waveguide 14, there is no particular upper limit, unless re-conversion to a high-order mode in the connection transparent tapered waveguide 14 occurs. However, it is desirable that the waveguide length L2 is short, in terms of size reduction of the element. For example, even in a case where the waveguide length L2 is set to be not greater than ten times the used wavelength for the purpose of size reduction of the optical semiconductor element, the effects of improving the tolerance for variation in the element structure and reducing the reflectance of a returning beam are obtained. The element structure in which W4 is equal to W2 as in the optical semiconductor element 510b shown in FIG. 5C also provides the same effects as the element structure shown in FIG. 5B.

In embodiment 1, the case where the transparent tapered waveguide 12 has a trapezoidal shape in a plan view has been described as an example. However, even in a case where both sides of the waveguide (oblique lines of the trapezoid) do not have straight line shapes but have curved line shapes symmetric with respect to the center position of the optical semiconductor element, as long as the waveguide has such a taper shape that the waveguide width monotonously decreases along the beam propagation direction from the first waveguide 10 side, it is possible to obtain an optical semiconductor element capable of conversion to such a guided mode shape that the circularity is high and coupling with an optical fiber is easy while the size is small and loss is low.

### Effects of Embodiment 1

As described above, the optical semiconductor element according to embodiment 1 has a configuration in which there is a focus position where the intensity of the propagating beam is focused at one location through interference between the fundamental mode beam and the high-order mode beam in the tapered waveguide, and the transparent tapered waveguide and the second waveguide are connected at the focus position, thus providing an effect of making it possible to obtain an optical semiconductor element in which a guided beam having such a guided mode shape that the spot size in the horizontal direction of the semiconductor substrate is large and the circularity is low can be converted to such a guided mode shape that the circularity is high and coupling with an optical fiber is easy.

### Embodiment 2

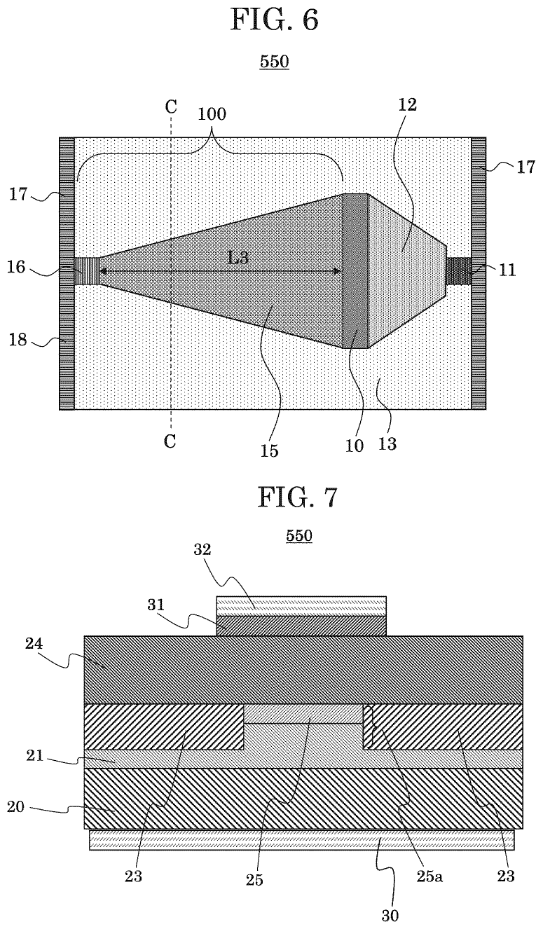

An optical semiconductor element 550 according to embodiment 2 is configured such that, as shown in FIG. 6, a gain waveguide portion 100 is connected to the first waveguide 10 of the element structure described in embodiment 1. FIG. 6 is a top view of the optical semiconductor element 550, as in FIG. 1A and FIG. 1B.

The optical semiconductor element 550 according to embodiment 2 includes, from the signal beam entrance side, a gain waveguide entrance portion 16, a gain tapered waveguide 15, the first waveguide 10, the transparent tapered waveguide 12, and the second waveguide 11. The gain waveguide entrance portion 16 and the gain tapered waveguide 15 form the gain waveguide portion 100. A low-reflectance coating film 17 is provided at an exit-side end surface of the optical semiconductor element 550, and a low-reflectance coating film 18 is provided at an entrance-side end surface thereof.

The first waveguide 10, the second waveguide 11, and the transparent tapered waveguide 12 are the same as those in the element structure shown in FIG. 1A, i.e., the optical semiconductor element 500 according to embodiment 1. In the gain waveguide portion 100, the gain waveguide entrance portion 16 and the gain tapered waveguide 15 are connected in this order from the signal beam entrance side. The gain tapered waveguide 15 is connected to the first waveguide 10 on the end side opposite to the gain waveguide entrance portion 16.

While a signal beam enters the optical semiconductor element 550 from the gain waveguide entrance portion 16 side and exits from the second waveguide 11 side, the beam intensity of the signal beam is amplified in the gain waveguide portion 100. Since the low-reflectance coating film 17 is provided at the exit-side end surface of the optical semiconductor element 550 and the low-reflectance coating film 18 is provided at the entrance-side end surface thereof, it is possible to prevent occurrence of a phenomenon such as wavelength ripple of a gain spectrum due to interference of returning beams reflected from both end surfaces, so that the optical semiconductor element 550 can operate as an optical amplifier that is reduced in wavelength dependency.

### Manufacturing /method for Optical Semiconductor Element According to Embodiment 2

FIG. 7 is a sectional view of the optical semiconductor element 550 according to embodiment 2 at a C-C line position in FIG. 6. A gain wavequide core layer 25 is laminated above the semiconductor substrate 20 and the lower cladding layer 21 which are the same as those in the element structure of embodiment 1 shown in FIG. 2. In order to form a gain waveguide mesa portion 25a, a part of the layers is removed by etching until reaching a certain position in the lower cladding layer 21 through the entire gain waveguide core layer 25, and the lateral cladding layer 23 is formed through crystal growth again. After the crystal growth, the upper cladding layer 24 is laminated, whereby the cross-section structure shown in FIG. 7 is formed. The etching and the crystal growth of the lateral cladding layer 23 can be performed in the same manner as in the case of forming the element structure of embodiment 1 shown in FIG. 2.

### Feature in Structure of Optical Semiconductor Element According to Embodiment 2

Materials are selected so that the refractive index of the gain waveguide core layer 25 becomes higher than the refractive indices of the lower cladding layer 21, the lateral cladding layer 23, and the upper cladding layer 24. The gain waveguide core layer 25 has an optical gain in element driving. Examples of the materials are as follows: the semiconductor substrate 20, the lower cladding layer 21, the lateral cladding layer 23, and the upper cladding layer 24 are made of InP, and the gain waveguide core layer 25 is formed by a multiple quantum well layer of InGaAsP or InAIGaAs which is a composition having an optical gain for a beam having a used wavelength when current is injected in the forward direction. These layers can be formed by epitaxial crystal growth above the semiconductor substrate, using a known crystal growth technique.

Also in a cross-section other than the cross-section at a C-C line position in FIG. 6, a similar cross-section structure is exhibited except that the waveguide width of the gain waveguide core layer 25 is different.

For current injection, for example, n-InP which is n-type doped is used for the semiconductor substrate 20 and the lower cladding layer 21, and p-InP which is p-type doped is used for the upper cladding layer 24, while the gain waveguide core layer 25 is intentionally set to be not doped. For the lateral cladding layer 23, known semi-insulating Fe-doped InP which is used for current confinement, or known p-n junction-provided InP formed to have a reverse biased state at the interface between p-InP and n-InP so as to increase the resistance, is used.

As electrodes for applying forward voltage, a lower electrode 30 is provided on the back surface of the semiconductor substrate 20, and a contact layer 31 and an upper electrode 32 are provided above the upper cladding layer 24. Examples of the layer thicknesses are as follows: the lower cladding layer 21 has a thickness of 0.5 μm, the gain waveguide core layer 25 has a thickness of 0.2 μm, and the upper cladding layer 24 has a thickness of 2.0 μm.

At the interface with the first waveguide 10, the specifications of the gain waveguide core layer 25 and the transparent waveguide core layer 22 are preferably adjusted so that the mode size in the thickness direction of the semiconductor substrate 20 does not differ between the transparent waveguide and the gain waveguide, in order to avoid increase in propagation loss due to mismatch of guided mode shapes at the above interface.

In the optical semiconductor element 550 according to embodiment 2 having the element structure as described above, current injected from the upper electrode 32 efficiently reaches the gain waveguide core layer 25, whereby an optical gain for a beam having a used wavelength can be produced.

As described in embodiment 1, the transparent tapered waveguide 12 is adjusted so that the fundamental mode beam at the connection part on the first waveguide 10 side is coupled with the second waveguide 11 at low loss. Therefore, in order to couple the fundamental mode signal beam entering the gain waveguide portion 100 with the second wavequide 11 at as low loss as possible, it is necessary that, in a signal beam amplified at the connection part between the gain tapered waveguide 15 and the first waveguide 10, the beam intensity of a fundamental mode beam is dominant as compared to the beam intensity of a high-order mode beam that can be excited in the gain tapered waveguide 15.

In other words, it is necessary that, in the gain tapered waveguide 15, a signal beam is guided adiabatically in an optical sense and a spot size is expanded while hardly exciting a high-order mode. For this purpose, the shape of the gain tapered wavequide 15 needs to be a thin elongated shape having a taper angle not greater than an upper limit for adiabatically guiding a beam. An example for satisfying the above condition is as follows: the waveguide width W1 on the first waveguide 10 side is 10 μm and the waveguide length L3 of the gain tapered wavequide 15 is not smaller than=400 μm.

The upper limit taper angle for adiabatically guiding a beam changes depending on the structure of the gain tapered waveguide 15, i.e., the thickness of the gain waveguide core layer 25 and a refractive index difference from the cladding layer. As the thickness of the gain waveguide core layer 25 becomes smaller, change in the effective refractive index of the guided mode relative to change in the waveguide width becomes smaller, and therefore conversion from the fundamental mode to a high-order mode becomes less likely to occur. In other words, it becomes possible to use the gain tapered waveguide 15 having a taper shape with a shorter waveguide length and a greater taper angle, with respect to the same waveguide width W1.

As the composition of the gain wavequide core layer 25 is set for a shorter wavelength, a refractive index difference from the cladding layer becomes smaller, so that change in the effective refractive index of the guided mode relative to change in the waveguide width becomes smaller. Thus, as in the above case, it becomes possible to use the gain tapered waveguide 15 having a taper shape with a shorter waveguide length and a greater taper angle.

In the optical semiconductor element 550 according to embodiment 2, the waveguide width of the gain tapered waveguide 15 can be increased as compared to a known semiconductor optical amplifier using a waveguide having a constant width, whereby the photon density in the waveguide in beam amplification is reduced, so that a gain saturation phenomenon is suppressed, thus providing an effect that all output beams from the gain tapered waveguide 15 can have high output levels.

### Modification 1 of Embodiment 2

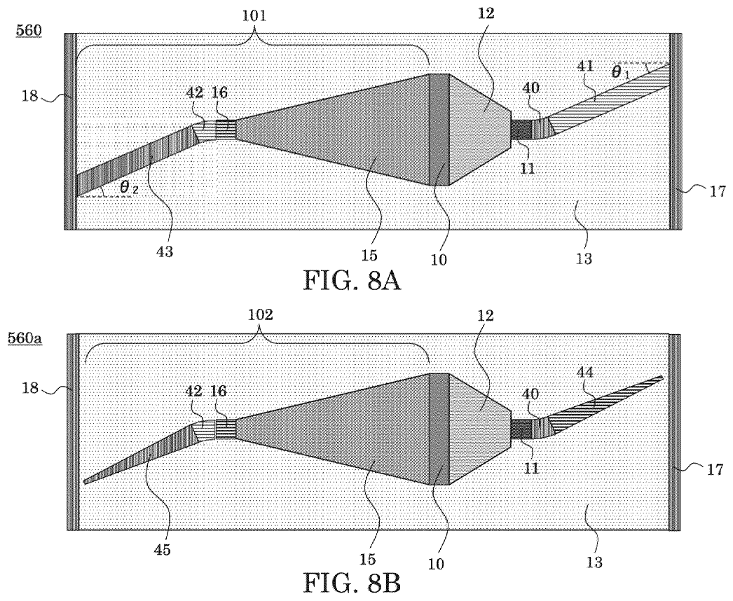

FIG. 8A and FIG. 8B are top views of an optical semiconductor element 560 and an optical semiconductor element 560a according to modification 1 of embodiment 2. The optical semiconductor element 560 shown in FIG. 8A includes, from the signal beam entrance side, an oblique gain waveguide 43, a bent gain waveguide 42, the gain waveguide entrance portion 16, the gain tapered waveguide 15, the first waveguide 10, the transparent tapered waveguide 12, the second waveguide 11, a bent waveguide 40, an oblique waveguide 41, and the lateral cladding region 13. The low-reflectance coating film 17 is provided at an exit-side end surface of the optical semiconductor element 560, and the low-reflectance coating film 18 is provided at an entrance-side end surface thereof. The oblique gain waveguide 43, the bent gain waveguide 42, the gain waveguide entrance portion 16, and the gain tapered wavequide 15 form an oblique-entrance-provided gain waveguide portion 101.

The element structure of the optical semiconductor element 560 shown in FIG. 8A is configured such that a signal beam exiting from the second waveguide 11 is guided through the bent waveguide 40 and the oblique waveguide 41 to the exit-side end surface provided at the low-reflectance coating film 17, in the element structure of the optical semiconductor element 550 according to embodiment 2 shown in FIG. 6. The oblique wavequide 41 is tilted relative to the exit-side end surface by a tilt angle 01 as compared to a case where the waveguide is perpendicular to the exit-side end surface. The tilt angle θ₁ is, for example, 7 degrees.

When the tilt angle θ₁ is not smaller than 7 degrees, the reflectance of a beam returning from the exit-side end surface can be made smaller than in the case where the waveguide is perpendicular, whereby an operation as an optical amplifier that is further reduced in wavelength dependency can be performed.

Also for the gain waveguide entrance portion 16, similarly, the bent gain waveguide 42 and the oblique gain waveguide 43 are provided to form the oblique-entrance-provided gain wavequide portion 101, and a beam is guided to the entrance-side end surface provided at the low-reflectance coating film 18. The oblique gain waveguide 43 is tilted by a tilt angle θ₂ as compared to a case where the waveguide is perpendicular to the entrance-side end surface. The tilt angle θ₂ is, for example, 7 degrees. When the tilt angle θ₂ is not smaller than 7 degrees, the reflectance of a beam returning from the entrance-side end surface can be made smaller than the case where the waveguide is perpendicular, whereby an operation as an optical amplifier that is further reduced in wavelength dependency can be performed.

In the element structure of the optical semiconductor element 560a shown in FIG. 8B, a spot size conversion waveguide 44 having a thin taper shape is provided instead of the oblique waveguide 41 shown in FIG. 8A. In addition, a spot size conversion gain waveguide 45 having a thin taper shape is provided instead of the oblique gain wavequide 43 shown in FIG. 8A, to form a spot-size-conversion-imparted gain waveguide 102. With this element structure, loss in coupling with an optical fiber when a signal beam is inputted/outputted using the optical fiber can be reduced, whereby an optical amplifier having a greater gain can be realized.

### Modification 2 of Embodiment 2

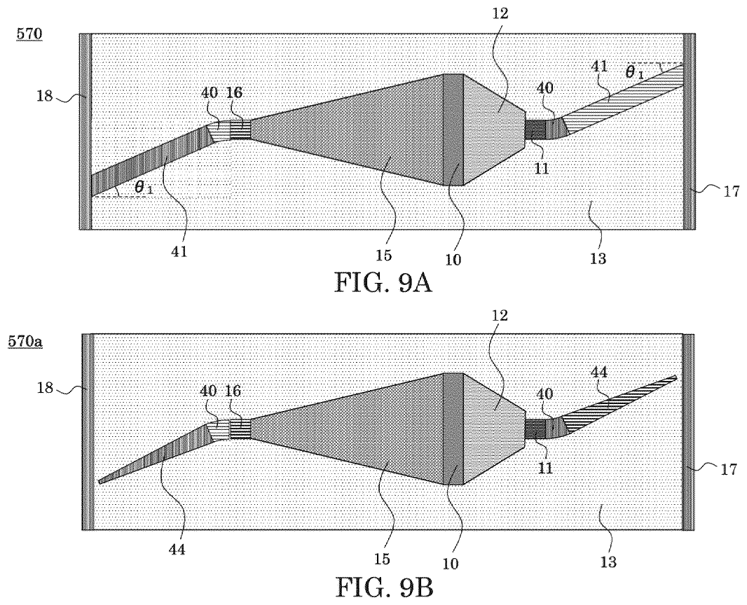

FIG. 9A and FIG. 9B are top views of an optical semiconductor element 570 and an optical semiconductor element 570a according to modification 2 of embodiment 2. The optical semiconductor element 570 shown in FIG. 9A has an element structure in which the bent waveguide 40 and the oblique waveguide 41 which are transparent waveguides are provided instead of the bent gain waveguide 42 and the oblique gain waveguide 43, as compared to the optical semiconductor element 560 shown in FIG. 8A.

The optical semiconductor element 570a shown in FIG. 9B has an element structure in which the spot size conversion waveguide 44 is provided instead of the oblique waveguide 41, as compared to the optical semiconductor element 570 shown in FIG. 9A. Even with these element structures, as in the case of the element structure shown in FIG. 8A, loss in coupling with an optical fiber when a signal beam is inputted/outputted using the optical fiber can be reduced, whereby an optical amplifier having a greater gain can be realized.

### Modification 3 of Embodiment 2

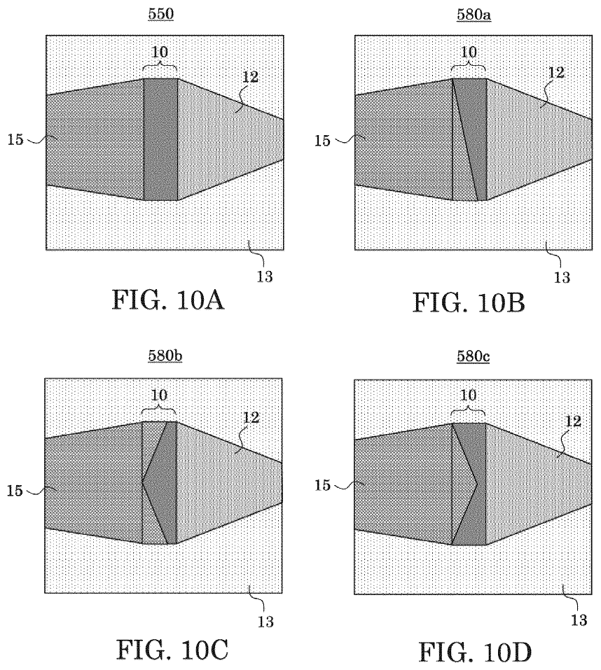

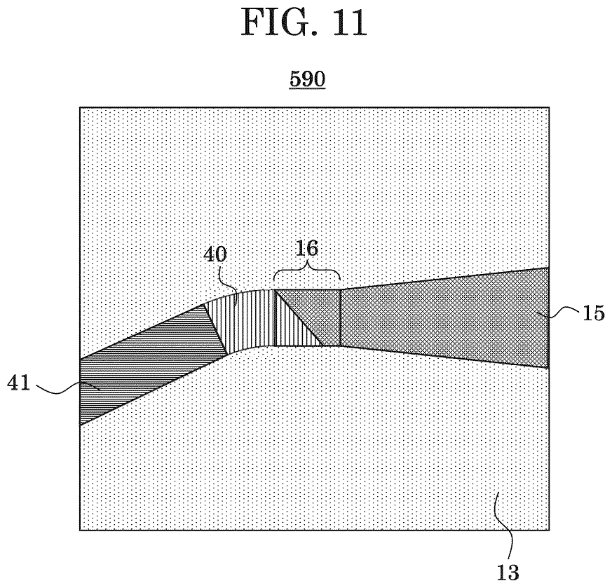

FIG. 10A is an enlarged view of a part around the first waveguide 10 in the element structure of the optical semiconductor element 550 according to embodiment 2 shown in FIG. 6. FIG. 10B, FIG. 10C, and FIG. 10D are top views showing an optical semiconductor element 580a, an optical semiconductor element 580b, and an optical semiconductor element 580c according to modification 3 of embodiment 2.

In the element structures shown in FIG. 10B to FIG. 10D, the waveguide core layer in a partial region contacting with the gain tapered waveguide 15, of the first waveguide 10, is formed by the gain waveguide core layer 25. In these element structures, the interface between the gain waveguide core layer 25 and the transparent waveguide core layer 22 is tilted relative to the beam propagation direction of the wavequide.

In the element structures shown in FIG. 10B to FIG. 10D, the reflectance of a returning beam reflected at the interface between the gain waveguide core layer 25 and the transparent waveguide core layer 22 is reduced as compared to the element structure shown in FIG. 10A, whereby an ideal optical amplifier can be formed.

### Modification 4 of embodiment 2

FIG. 11 is a top view of an optical semiconductor element 590 according to modification 4 of embodiment 2, which has such an element structure that, in the element structure shown in FIG. 9A, a part of the gain waveguide entrance portion 16 on a side not contacting with the gain tapered waveguide 15 is formed by the transparent waveguide core layer 22, and the interface between the gain waveguide core layer 25 and the transparent waveguide core layer 22 is tilted relative to the beam propagation direction of the waveguide.

In the element structure shown in FIG. 11, the reflectance of a returning beam reflected at the interface between the gain waveguide core layer 25 and the transparent waveguide core layer 22 is reduced as compared to the element structure shown in FIG. 9A, whereby an ideal optical amplifier can be formed. Not only in the element structure shown in FIG. 9A but also in the element structure shown in FIG. 9B, the gain waveguide entrance portion 16 can be provided with an oblique interface, so that the reflectance of a returning beam is similarly reduced, whereby an ideal optical amplifier can be formed.

### Effects of Embodiment 2

As described above, in the optical semiconductor element according to embodiment 2, the gain waveguide is appropriately connected to the element structure of the optical semiconductor element according to embodiment 1, thus providing an effect that an amplified signal beam can be converted to such a guided mode shape that the circularity is high and coupling with an optical fiber is easy while the size is small and loss is low.

### Embodiment 3

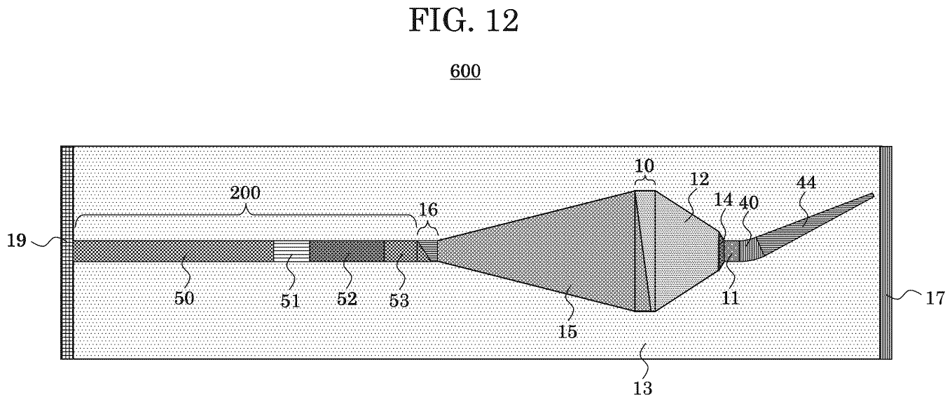

FIG. 12 is a top view of an optical semiconductor element 600 according to embodiment 3. The optical semiconductor element 600 according to embodiment 3 includes, from the signal beam entrance side, a laser light source portion 50, a laser optical modulator connection part 51, an optical modulator portion 52, an optical modulator gain waveguide connection part 53, the gain waveguide entrance portion 16, the gain tapered waveguide 15, the first wavequide 10, the transparent tapered waveguide 12, the connection transparent tapered waveguide 14, the second wavequide 11, the bent waveguide 40, the spot size conversion waveguide 44, and the lateral cladding region 13. The laser light source portion 50, the laser optical modulator connection part 51, the optical modulator portion 52, and the optical modulator gain waveguide connection part 53 form a modulated signal beam generation portion 200. A high-reflectance coating film 19 is provided at an exit-side end surface of the optical semiconductor element 600, and a low-reflectance coating film 18 is provided at an entrance-side end surface thereof.

The optical semiconductor element 600 according to embodiment 3 is characterized in that, as shown in FIG. 12, the modulated signal beam generation portion 200 is connected to the gain wavequide entrance portion 16 of the optical semiconductor element 550 according to embodiment 2. In the modulated signal beam generation portion 200 of the optical semiconductor element 600 shown in FIG. 12, the laser light source portion 50 which is a distributed feedback semiconductor laser (DFB laser) and the optical modulator portion 52 which is an electro absorption optical modulator are connected to each other via the laser optical modulator connection part 51 which is a transparent waveguide, and the optical modulator portion 52 is connected to the gain waveguide entrance portion 16 via the optical modulator gain waveguide connection part 53 which is a transparent waveguide.

As the modulated signal beam generation portion 200, other configurations such as a direct modulation semiconductor laser, a semiconductor laser with a Mach-Zehnder optical modulator, and a semiconductor laser with a microring optical modulator, may be adopted.

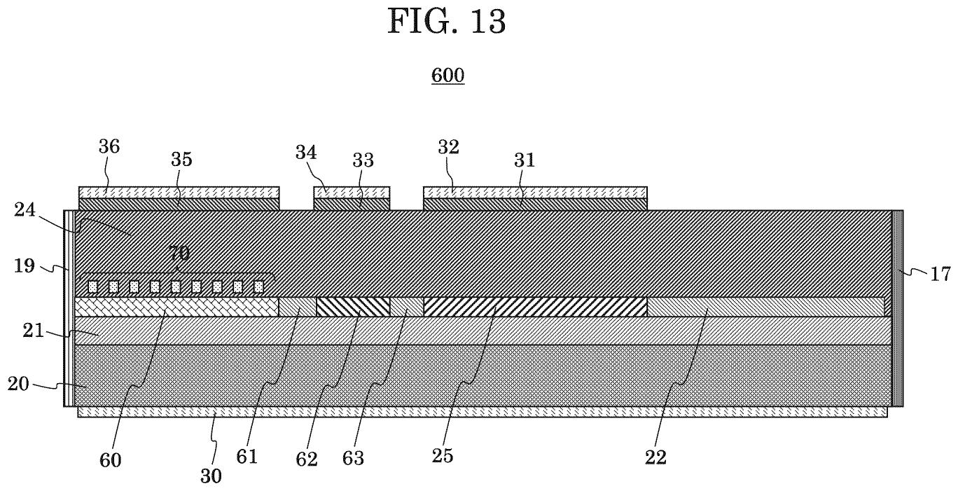

FIG. 13 is a sectional view of the element structure of the optical semiconductor element 600 according to embodiment 3 shown in FIG. 12 along a direction parallel to the substrate thickness direction and shows a cross-section (not flat) along the center line of the straight and bent waveguides. The cross-section from the laser light source portion 50 to the bent waveguide 40 is a cross-section along a direction perpendicular to the substrate end surface, and the cross-section from the bent waveguide 40 to the spot size conversion waveguide 44 is a cross-section along a direction tilted relative to the substrate end surface.

In the optical semiconductor element 600 according to embodiment 3, from the signal beam entrance side, a laser active layer 60, a transparent waveguide core layer 61, an optical modulator active layer 62, a transparent waveguide core layer 63, the gain waveguide core layer 25, and the transparent waveguide core layer 22 are provided as layers through which a signal beam is guided.

The semiconductor substrate 20, the lower cladding layer 21, and the upper cladding layer 24 are the same as those in the element structure of the optical semiconductor element 550 according to embodiment 2. The lower electrode 30 is provided on the back surface of the semiconductor substrate 20. Further, a contact layer 35 and an upper electrode 36 for injecting current are provided at the laser light source portion 50. The laser active layer 60 which is intentionally not doped with dopants is laminated on the lower cladding layer 21, and the diffraction grating 70 for outputting a used-wavelength beam as a distributed feedback semiconductor laser is provided closely above the laser active layer 60. The diffraction grating 70 may have a structure in which a known phase shift part where a diffraction grating interval is different is provided, and it is known that this structure has an effect of stabilizing single mode oscillation of a semiconductor laser. The high-reflectance coating film 19 is provided at the entrance-side end surface on the laser light source portion 50 side so that an output beam to the gain tapered waveguide 15 side increases.

The transparent waveguide core layer 61 and the transparent waveguide core layer 63 are formed together with the same composition and thickness as the transparent waveguide core layer 22. The optical modulator active layer 62 is formed by a multiple quantum well layer adjusted so that a quantum confined Stark effect occurs upon reverse bias application and an absorption coefficient in an absorption edge nearby wavelength band increases, while the oscillation wavelength of the laser light source portion 50 is in the absorption edge nearby wavelength band. For applying a reverse bias to the optical modulator active layer 62, the contact layer 33 and the upper electrode 34 are provided.

The laser optical modulator connection part 51 and the optical modulator gain waveguide connection part 53 are formed to have waveguide lengths needed for preventing resistance reduction in electrical separation between the upper electrode 36, the upper electrode 34, and the upper electrode 32. As an example of the waveguide lengths, the waveguide lengths of the laser optical modulator connection part 51 and the optical modulator gain waveguide connection part 53 are 50 μm.

In the optical semiconductor element 600 according to embodiment 3, forward voltage which is independent and constant voltage is applied between the upper electrode 36 and the upper electrode 32, to drive the laser light source portion 50 and the gain waveguide portion 100. Appropriate reverse bias voltage and a modulated electric signal on which a high-frequency voltage signal encoded for optical communication is superimposed are applied to the upper electrode 34. The absorption coefficient of the optical modulator portion 52 changes in accordance with the applied modulated electric signal, so that a modulated signal beam is generated.

The modulated signal beam enters the gain waveguide portion 100, in which the beam intensity is amplified while the fundamental mode is dominant, and then reaches the first waveguide 10. Subsequently, as the modulated signal beam propagates through the transparent tapered waveguide 12, the modulated signal beam is converted to such a guided mode shape that the circularity is high and coupling with an optical fiber is easy while the size is small and loss is low, and reaches the second waveguide 11. Finally, the modulated signal beam exits from the spot size conversion waveguide 44.

### Effects of Embodiment 3

As described above, in the optical semiconductor element according to embodiment 3, the modulated signal beam generation portion is further provided, thus providing an effect that the output level of a modulated beam signal is increased by the optical amplifier and the modulated beam signal can be taken out as an exited beam formed in a favorable beam shape.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

10 first waveguide
11 second waveguide
12 transparent tapered waveguide
13 lateral cladding region
14 connection transparent tapered waveguide
15, 82 gain tapered waveguide
16 gain waveguide entrance portion
17, 18 low-reflectance coating film
19 high-reflectance coating film
20 semiconductor substrate
21 lower cladding layer
22 transparent waveguide core layer
22a transparent waveguide mesa portion
23 lateral cladding layer
24 upper cladding layer
25 gain waveguide core layer
25a gain waveguide mesa portion
30, 32 lower electrode
31, 33, 35 contact layer
32, 34, 36 upper electrode
40 bent wavequide
41 oblique waveguide
42 bent gain waveguide
43 oblique gain waveguide
44 spot size conversion waveguide
45 spot size conversion gain wavequide
50 laser light source portion
51 laser optical modulator connection part
52 optical modulator portion
53 optical modulator gain waveguide connection part
60 laser active layer
61, 63 transparent waveguide core layer
62 optical modulator active layer
70 diffraction grating
80 gain first waveguide
81 gain second waveguide
100 gain waveguide portion
101 oblique-entrance-provided gain waveguide portion
102 spot-size-conversion-imparted gain waveguide
200 modulated signal beam generation portion
500, 500a, 510a, 510b, 550, 560, 560a, 570, 570a, 580a, 580b, 580c, 590, 600 optical semiconductor element

1.-9. (canceled)

10. An optical semiconductor element comprising:
a first waveguide which is formed above a semiconductor substrate and in which a propagating beam in a high-order mode is allowed;
a tapered waveguide which is formed above the semiconductor substrate and of which one end is connected to another end of the first waveguide and a waveguide width decreases toward another end of the tapered waveguide;
a second waveguide which is formed above the semiconductor substrate and of which one end is connected to the tapered waveguide, the second waveguide having a smaller waveguide width than a waveguide width of the first waveguide and being a transparent waveguide that is transparent for a wavelength of the propagating beam; and
a gain tapered waveguide formed above the semiconductor substrate and having a gain waveguide core layer which has an optical gain, the gain tapered waveguide having such a shape that a waveguide width thereof increases along a beam propagation direction, wherein
the tapered waveguide is a transparent tapered waveguide that is transparent for the wavelength of the propagating beam, and has such a taper shape that a high-order mode beam is excited in the tapered waveguide as a fundamental mode beam entering from the other end of the first waveguide propagates,
the gain tapered waveguide, the first waveguide, and the tapered waveguide are arranged in this order along the beam propagation direction, and
there is a focus position where an intensity of the propagating beam is focused at one location through interference between the fundamental mode beam and the high-order mode beam in the tapered waveguide, and the tapered waveguide and the second waveguide are connected at the focus position.

11. The optical semiconductor element according to claim 10, wherein the focus position is a position where a beam entering from the first waveguide is first focused while propagating.

12. The optical semiconductor element according to claim 10, wherein
at a connection part where the other end of the tapered waveguide and the one end of the second waveguide are connected, a waveguide width of the other end of the tapered waveguide is greater than a waveguide width of the one end of the second waveguide.

13. The optical semiconductor element according to claim 10, wherein
where a waveguide length in the beam propagation direction of the tapered waveguide is denoted by L and a waveguide width of the one end of the tapered waveguide at a connection part between the other end of the first waveguide and the one end of the tapered waveguide is denoted by W, L/W which is a ratio of the waveguide length L and the waveguide width W is not greater than 10.

14. The optical semiconductor element according to claim 10, wherein
the gain tapered waveguide has such a taper shape that occurrence of the high-order mode is suppressed when a beam entering from a side of the gain tapered waveguide where the waveguide width thereof is small propagates in the gain tapered waveguide.

15. The optical semiconductor element according to claim 10, further comprising a modulated signal beam generation portion which is formed above the semiconductor substrate and modulates the propagating beam, wherein
an entrance side of the gain tapered waveguide is connected to an exit side of the modulated signal beam generation portion.

16. The optical semiconductor element according to claim 15, wherein
a laser light source portion which generates a laser beam in the modulated signal beam generation portion, and an optical modulator portion which performs optical modulation for the laser beam generated by the laser light source portion and outputs a modulated laser beam, are provided, and
in the modulated signal beam generation portion, the laser light source portion, the optical modulator portion, and the gain tapered waveguide are arranged in this order along the beam propagation direction.

17. An optical semiconductor element comprising:
a first waveguide which is formed above a semiconductor substrate and in which a propagating beam in a high-order mode is allowed;
a first gain tapered waveguide which is formed above the semiconductor substrate and of which one end is connected to another end of the first waveguide and a waveguide width decreases toward another end of the first gain tapered waveguide, the first gain tapered waveguide being formed by a gain waveguide having a gain waveguide core layer which has an optical gain;
a second waveguide which is formed above the semiconductor substrate and of which one end is connected to the first gain tapered waveguide, the second waveguide having a smaller waveguide width than a waveguide width of the first waveguide; and
a second gain tapered waveguide formed above the semiconductor substrate and connected to one end of the first waveguide, the second gain tapered waveguide having such a shape that a waveguide width thereof increases along a beam propagation direction, the second gain tapered waveguide being formed by the gain waveguide, wherein
the first gain tapered waveguide has such a taper shape that a high-order mode beam is excited in the first gain tapered waveguide as a fundamental mode beam entering from the other end of the first waveguide propagates, there is a focus position where an intensity of the propagating beam is focused at one location through interference between the fundamental mode beam and the high-order mode beam in the first gain tapered waveguide, and the first gain tapered waveguide and the second waveguide are connected at the focus position.

18. The optical semiconductor element according to claim 17, wherein
the focus position is a position where a beam entering from the first waveguide is first focused while propagating.

19. The optical semiconductor element according to claim 17, wherein
at a connection part where the other end of the first gain tapered waveguide and the one end of the second waveguide are connected, a waveguide width of the other end of the first gain tapered waveguide is greater than a waveguide width of the one end of the second waveguide.

20. The optical semiconductor element according to claim 17, wherein
where a waveguide length in the beam propagation direction of the first gain tapered waveguide is denoted by L and a waveguide width of the one end of the first gain tapered waveguide at a connection part between the other end of the first waveguide and the one end of the first gain tapered waveguide is denoted by W, L/W which is a ratio of the waveguide length L and the waveguide width W is not greater than 10.

21. The optical semiconductor element according to claim 17, wherein
the second waveguide is formed by a gain waveguide.

22. The optical semiconductor element according to claim 17, wherein
the second waveguide is a transparent waveguide that is transparent for the wavelength of the propagating beam.

23. The optical semiconductor element according to claim 17, wherein
the second gain tapered waveguide has such a taper shape that occurrence of the high-order mode is suppressed when a beam entering from a side of the second gain tapered waveguide where the waveguide width is small propagates in the second gain tapered waveguide.

24. The optical semiconductor element according to claim 17, further comprising a modulated signal beam generation portion which is formed above the semiconductor substrate and modulates the propagating beam, wherein
an entrance side of the second gain tapered waveguide is connected to an exit side of the modulated signal beam generation portion.

25. The optical semiconductor element according to claim 24, wherein
a laser light source portion which generates a laser beam in the modulated signal beam generation portion, and an optical modulator portion which performs optical modulation for the laser beam generated by the laser light source portion and outputs a modulated laser beam, are provided, and
in the modulated signal beam generation portion, the laser light source portion, the optical modulator portion, and the second gain tapered waveguide are arranged in this order along the beam propagation direction.
